(19) United States
(12) Patent Application Publication
(10) Pub. No.: US 2013/0106263 A1
(43) Pub. Date: May 2, 2013

(54) BACKLIGHT MODULE

(71) Applicants: Shih-hsiang Chen, Shenzhen (CN); Ruilian Yang, Shenzhen (CN)

(72) Inventors: Shih-hsiang Chen, Shenzhen (CN); Ruilian Yang, Shenzhen (CN)

(73) Assignee: Shenzhen China Star Optoelectronics Technology Co, LTD., Shenzhen, Guangdong (CN)

(21) Appl. No.: 13/380,031

(22) PCT Filed: Nov. 11, 2011
(86) PCT No.: PCT/CN11/82096

§ 371 Date: Dec. 21, 2011

(30) Foreign Application Priority Data
Nov. 2, 2011 (CN) 201120429469.9

(51) Int. Cl. H05K 5/02

(52) U.S. Cl. 312/223.5

(57) ABSTRACT

A backlight module includes a front frame, a plastic frame, and a connecting structure. The front frame includes a rear surface and at least one first protrusion perpendicularly protruding from the rear surface. The plastic frame includes a front surface facing the rear surface and at least one second protrusion perpendicularly protruding from the front surface. The connecting structure includes at least one first abutting portion disposed on the at least one first protrusion and at least one second abutting portion disposed on the at least one second protrusion and capable of engaging with the at least one first protrusion. With the connecting structure, the front frame can be fixed to the plastic frame without using tools, and the front frame can prevented from being tilted outwards easily to avoid an unwanted gap between the front frame and a liquid crystal panel.

### BACKGROUND

1. Technical Field

The present disclosure relates to liquid crystal displaying technologies, and particularly, to backlight module for a liquid crystal panel.

2. Description of Related Art

Backlight module is one of the key components of liquid crystal panels for supplying adequate and uniform light. A backlight module usually includes a front frame, a liquid crystal panel, a light guide plate, a plastic frame, and a back plate. The front frame is fixed to the back plate by screws or hooks. When fixed by the screws, the front frame needs to be tapped and screwed, which is time-consuming. When fixed by the hooks, the front frame is usually hooked to the back plate via hooks disposed on the edges of the back surface thereof. In this way, the front frame can be fixed to the back plate easily, however, the front frame may be easily deformed outwards to result in a large gap between the front frame and the liquid crystal panel.

Therefore, there is room for improvement.

### SUMMARY

The present disclosure provides a backlight module. The backlight module includes a front frame, a plastic frame, and a connecting structure. The front frame includes a rear surface and at least one first protrusion perpendicularly protruding from the rear surface. The plastic frame includes a front surface facing the rear surface and at least one second protrusion perpendicularly protruding from the front surface. The connecting structure includes at least one first abutting portion disposed on the at least one first protrusion and at least one second abutting portion disposed on the at least one second protrusion and capable of engaging with the at least one first protrusion. Each first abutting portion includes a first sliding surface and a first abutting surface, and the first abutting surface is capable of abutting the corresponding second protrusion. Each second abutting portion includes a second sliding surface slidably engaging with the corresponding first sliding surface and a second abutting surface, and the second abutting surface is capable of abutting the corresponding first protrusion and an area thereof being larger than that of the corresponding first abutting surface.

Preferably, the at least one first protrusion and the at least one second protrusion are cylindrical, and each second protrusion is sleeved by the corresponding first protrusion.

Preferably, the front frame further includes at least one third protrusion perpendicularly protruding from the rear surface and surrounded by the at least one first protrusion.

Preferably, each first protrusion is capable of engaging with the corresponding third protrusion to clamp the corresponding second protrusion.

Preferably, the front frame includes two of the first protrusions arranged side by side, each first protrusion is substantially rectangular, the plastic frame comprises two of the second protrusions arranged side by side, and each second protrusion is substantially rectangular.

The present disclosure further provides another backlight module. The backlight module includes a front frame, a plastic frame, and a connecting structure disposed on the front frame and the plastic frame for connecting the front frame and the plastic frame.

Preferably, the front frame includes a rear surface, the plastic frame includes a front surface facing the rear surface, the connecting structure includes at least one first abutting portion arranged on the rear surface and at least one second abutting portion arranged on the front surface, the first abutting portion is capable of engaging with the second abutting portion.

Preferably, the front frame includes at least one first protrusion perpendicularly protruding from the rear surface, the at least one first abutting portion is disposed on the at least one first protrusion; the plastic frame includes at least one second protrusion perpendicularly protruding form the front surface of the plastic frame, the at least one second abutting portion is disposed on the at least one second protrusion.

Preferably, the at least one first protrusion and the at least one second protrusion are cylindrical, and each first protrusion sleeves the corresponding second protrusion.

Preferably, the front frame includes two of the first protrusions arranged side by side, each first protrusion is substantially rectangular; the plastic frame includes two of the second protrusions arranged side by side, and each second protrusion is substantially rectangular.

Preferably, the front frame further includes at least one third protrusion perpendicularly protruding from the rear surface and surrounded by the at least one first protrusion.

Preferably, each first protrusion is capable of engaging with the corresponding third protrusion to clamp the corresponding second protrusion.

Preferably, each first protrusion is capable of engaging with the corresponding third protrusion to clamp the corresponding second protrusion.

Preferably, each first abutting portion includes a first sliding surface for slidably engaging with the corresponding second abutting portion.

Preferably, each second abutting portion includes a second sliding surface for slidably engaging with the corresponding first abutting portion.

Preferably, each first abutting portion includes a first abutting surface, each second abutting portion includes a second abutting surface, a part of the first abutting portion is capable of being inserted into the corresponding second protrusion to allow the first abutting surface to abut the second protrusion, a part of the second abutting portion is capable of being inserted into the corresponding first protrusion to allow the second abutting surface to abut the first protrusion.

With the connecting structure, the front frame and the plastic frame can be detachably assembled to each other without using any other tool. Also, with the first and second abutting portions respectively disposed on the rear surface of the front frame and the front surface of the plastic frame, no force is added to the rear surface and thus the front frame may not be tilted outwards easily. Therefore, an unwanted gap between the front frame and the crystal panel can be avoided.

### DESCRIPTION OF THE DRAWINGS

Many aspects of the embodiments can be better understood with reference to the following drawings. The components in the drawings are not necessarily dawns to scale, the emphasis instead being placed upon clearly illustrating the principles of the embodiments. Moreover, in the drawings, like reference numerals designate corresponding parts throughout the several views.

FIG. 1 is a cross section view of a backlight module in according with an embodiment of the present disclosure. The backlight module includes a front frame with a first abutting portion disposed thereon and a plastic frame with a second abutting portion disposed thereon.

FIG. 2 is a top view of the front frame of the backlight module of FIG. 1.

FIG. 3 is a cross-sectional view of FIG. 2 taken along a line A-A.

FIG. 4 is a top view of the plastic frame of the backlight module of FIG. 1.

FIG. 5 is a cross-sectional view of FIG. 4 taken along the line A-A.

FIG. 6 is an enlarged view of a portion A of FIG. 1.

FIG. 7 is a top view of the front frame of FIG. 1 in accordance with another embodiment.

FIG. 8 is a top view of the plastic frame of FIG. 1 in accordance with another embodiment.

### DETAILED DESCRIPTION

The disclosure is illustrated by way of example and not by way of limitation in the figures of the accompanying drawings in which like references indicate similar elements. It should be noted that references to “an” or “one” embodiment is this disclosure are not necessarily to the same embodiment, and such references mean at least one.

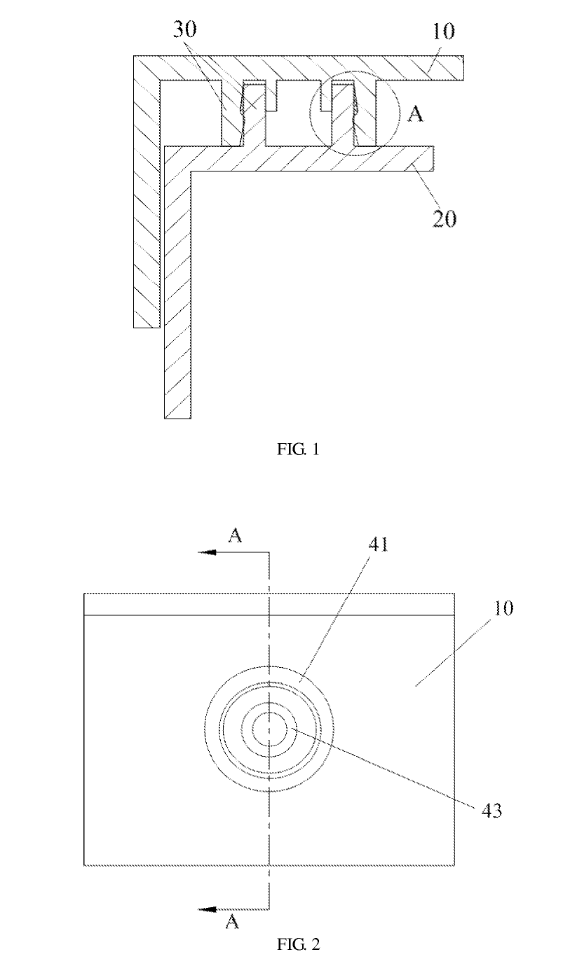

Referring to FIG. 1, a backlight module in accordance with an embodiment of the present disclosure includes a front frame 10, a plastic frame 20, and a connecting structure 30 for connecting the front frame 10 with the plastic frame 20.

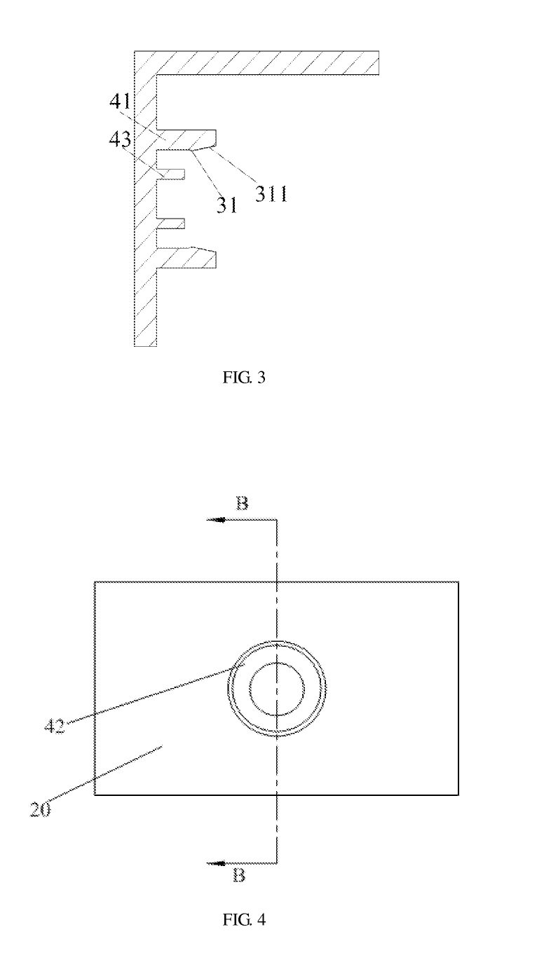

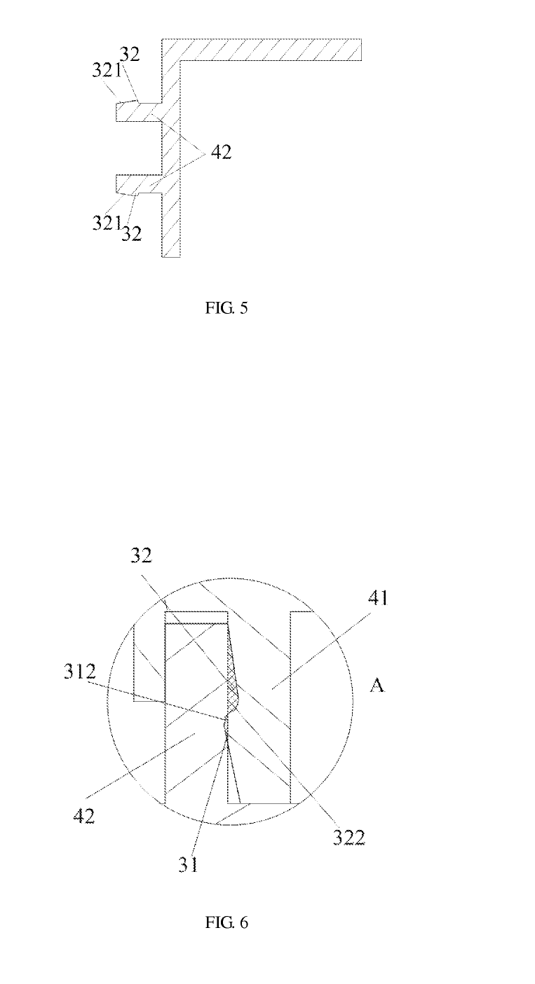

Referring to FIGS. 2 to 5, the front frame 10 includes a rear surface, and a first protrusion 41 and a third protrusion 43 perpendicularly protruding from the rear surface. Both the first and third protrusions 41, 43 are cylindrical and the first protrusion 41 sleeves the third protrusion 43.

The plastic frame 20 includes a front surface facing the rear surface and a second protrusion 42 perpendicularly protruding from the front surface. In the embodiment, the second protrusion 42 is also cylindrical and capable of being clamped in a gap defined between the first and third protrusions 41, 43.

Also referring to FIG. 6, the connecting structure 30 includes an elastic first abutting portion 31 and an elastic second abutting portion 32 detachably connected to the first abutting portion 31. The first abutting portion 31 is disposed on a free end of the first protrusion 41 which is away from the rear surface of the front frame 10. One side of the first abutting portion 31 facing the third protrusion 43 defines a first sliding surface 311. The first abutting portion 31 further includes a first abutting surface 312 connected to the first sliding surface 311.

The second abutting portion 32 is disposed on the free end of the second protrusion 42 which is away from the front surface of the plastic frame 20. One side of the second abutting portion 32 defines a second sliding surface 321 capable of slidably engaging with the first sliding surface 311 to allow the first abutting portion 31 to engage with the second abutting portion 32 quickly. The second abutting portion 32 further includes a second abutting surface 322 connected to the second sliding surface 321. An area of the second abutting surface 322 is larger than that of the first abutting surface 312.

It is noted that the first abutting portion 31 and the second abutting portion 32 is not limited to this embodiment. In some embodiments, the first abutting portion 31 may be a groove defined in the rear surface of the front frame 10, and the second abutting portion 32 may be a hook shaped protrusion protruding from the front surface of the plastic frame 10 to abut an inner surface of the groove. In some embodiments, the first abutting portion 31 may be a hook shaped protrusion protrudes from the rear surface of the front frame 10, and the second abutting portion 32 can be a groove defined in the front surface of the plastic frame 20 for being abutted by the protrusion. In some embodiments, both the first abutting portion 31 and the second abutting portion 32 may be hook shaped protrusions respectively protruding from the rear surface of the front frame 10 and the front surface of the plastic frame 20 for engaging with each other.

In assembly, the second protrusion 42 is inserted into the gap between the first and third protrusions 41, 43 easily with the engagement between the first and second sliding surfaces 311, 321. As the third protrusion 43 moves on, the first abutting portion 31 is capable of engaging with the second abutting portion 32 to drive the first and third protrusions 41, 43 to be deformed. After the third protrusion 43 is received in the gap between the first and third protrusions 41, 43, the first and third protrusions 41, 43 rebounds to allow the first abutting portion 31 to engage with the second abutting portion 32. At this time, a part of the first abutting portion 31 is inserted into the third protrusion 43 to allow the first abutting surface 312 thereof to abut the third protrusion 43, and a part of the second abutting portion 32 is inserted into the first protrusion 41 to allow the second abutting surface 322 thereof abutting the first protrusion 41. Therefore, the first and third protrusions 41, 43 engage with each other to clamp the second protrusion 42 in the gap therebetween to prevent the second protrusion 42 from moving away from the gap. In this state, the plastic frame 20 is fixed to the front frame 10 stably to allow the front frame 10 and the plastic frame to be assembled together.

In disassembly, the second protrusion 42 is pulled to allow the first abutting portion 31 to disengage from the second abutting portion 32. As such, the plastic frame 20 can be disconnected from the front frame 10.

It should be understood that in other embodiments, the third protrusion 43 can be omitted as long as the first abutting portion 31 can engage with the second abutting portion 32.

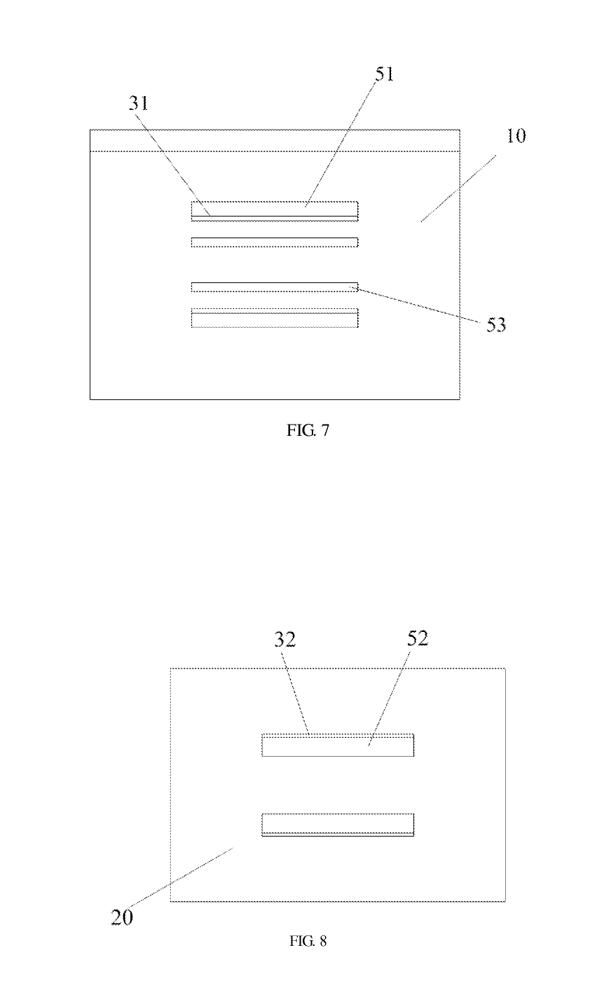

It should be understood that the configurations of the three protrusions are not limited to this embodiments. In other embodiments, the three protrusions may not be cylindrical. For example, referring to FIGS. 7 and 8, in another embodiment, the backlight module includes two substantially rectangular first protrusions 51 arranged side by side and two substantially rectangular third protrusions 53 arranged side by side between the two first protrusions 51. Two first abutting portions 31 respectively protrude from two sides of the first protrusions 51 and face each other. Two second abutting portions 32 respectively protrude from two sides of the second protrusions 52 and face away from each other. In this case, the first abutting portions 31 also can engage with the two second abutting portions 32 to connect the front frame 10 with the plastic frame 20.

With the first abutting portion 31 and the second abutting portion 32 of the present disclosure, the front frame 10 and the plastic frame 20 can be easily assembled together and disassembled from each other without using any other tool. Also, with the first and second abutting portions 31, 32 respectively disposed on the rear surface of the front frame 10 and the front surface of the plastic frame 20, no force is added to the rear surface and thus the front frame may not be tilted outwards easily. Therefore, an unwanted gap between the front frame 10 and the crystal panel can be avoided.

Even though information and the advantages of the present embodiments have been set forth in the foregoing description, together with details of the mechanisms and functions of the present embodiments, the disclosure is illustrative only; and that changes may be made in detail, especially in matters of shape, size, and arrangement of parts within the principles of the present embodiments to the full extend indicated by the broad general meaning of the terms in which the appended claims are expressed.

What is claimed is:

1. A backlight module, comprising:
a front frame, comprising a rear surface and at least one first protrusion perpendicularly protruding from the rear surface;
a plastic frame, comprising a front surface facing the rear surface and at least one second protrusion perpendicularly protruding from the front surface; and
a connecting structure, comprising:
at least one first abutting portion disposed on the at least one first protrusion, each first abutting portion comprising a first sliding surface and a first abutting surface, and the first abutting surface being capable of abutting the corresponding second protrusion; and
at least one second abutting portion disposed on the at least one second protrusion and capable of engaging with the at least one first protrusion, each second abutting portion comprising a second sliding surface slidably engaging with the corresponding first sliding surface and a second abutting surface, and the second abutting surface being capable of abutting the corresponding first protrusion and an area thereof being larger than that of the corresponding first abutting surface.

2. The backlight module of claim 1, wherein the at least one first protrusion and the at least one second protrusion are cylindrical, and each first protrusion sleeves the corresponding second protrusion.

3. The backlight module of claim 2, wherein the front frame further comprises at least one third protrusion perpendicularly protruding from the rear surface and surrounded by the at least one first protrusion.

4. The backlight module of claim 3, wherein each first protrusion is capable of engaging with the corresponding third protrusion to clamp the corresponding second protrusion.

5. The backlight module of claim 1, wherein the front frame comprises two of the first protrusions arranged side by side, each first protrusion is substantially rectangular; the plastic frame comprises two of the second protrusions arranged side by side, and each second protrusion is substantially rectangular.

6. The backlight module of claim 5, wherein the front frame further comprises two of the third protrusions arranged between the two first protrusions.

7. The backlight module of claim 6, wherein each first protrusion is capable of engaging with the corresponding third protrusion to clamp the corresponding second protrusion.

8. A backlight module, comprising a front frame, a plastic frame, and a connecting structure disposed on the front frame and the plastic frame for connecting the front frame and the plastic frame.

9. The backlight module of claim 8, wherein the front frame comprises a rear surface, the plastic frame comprises a front surface facing the rear surface, the connecting structure comprises at least one first abutting portion arranged on the rear surface and at least one second abutting portion arranged on the front surface, each first abutting portion is capable of engaging with the corresponding second abutting portion.

10. The backlight module of claim 9, wherein the front frame comprises at least one first protrusion perpendicularly protruding from the rear surface, the at least one first abutting portion is disposed on the at least one first protrusion, the plastic frame comprises at least one second protrusion perpendicularly protruding form the front surface of the plastic frame, and the at least one second abutting portion is disposed on the at least one second protrusion.

11. The backlight module of claim 10, wherein the at least one first protrusion and the at least one second protrusion are cylindrical, and each first protrusion sleeves the corresponding second protrusion.

12. The backlight module of claim 11, wherein the front frame further comprises at least one third protrusion perpendicularly protruding from the rear surface and surrounded by the at least one first protrusion.

13. The backlight module of claim 12, wherein each first protrusion is capable of engaging with the corresponding third protrusion to clamp the corresponding second protrusion.

14. The backlight module of claim 13, wherein the front frame comprises two of the first protrusions arranged side by side, each first protrusion is substantially rectangular;
the plastic frame comprises two of the second protrusions arranged side by side, and each second protrusion is substantially rectangular.

15. The backlight module of claim 14, wherein the front frame further comprises two of the third protrusions arranged between the two first protrusions.

16. The backlight module of claim 15, wherein each first protrusion is capable of engaging with the corresponding third protrusion to clamp the corresponding second protrusion.

17. The backlight module of claim 9, wherein each first abutting portion comprises a first sliding surface for slidably engaging with the corresponding second abutting portion.

18. The backlight module of claim 9, wherein each second abutting portion comprises a second sliding surface for slidably engaging with the corresponding first abutting portion.

19. The backlight module of claim 9, wherein each first abutting portion comprises a first abutting surface, each second abutting portion comprises a second abutting surface, a part of each first abutting portion is capable of being inserted into the corresponding second protrusion to allow the first abutting surface to abut the second protrusion, a part of each second abutting portion is capable of being inserted into the corresponding first protrusion to allow the second abutting surface to abut the first protrusion.
